(19) United States
(12) Patent Application Publication
(10) Pub. No.: US 2014/0118269 A1
(43) Pub. Date: May 1, 2014

(54) DISPLAY DEVICE

(71) Applicant: Kyu-Young KIM, Yongin-City (KR)

(72) Inventor: Kyu-Young KIM, Yongin-City (KR)

(21) Appl. No.: 13/765,859

(22) Filed: Feb. 13, 2013

(30) Foreign Application Priority Data
Nov. 1, 2012 (KR) 10-2012-0122878

(51) Int. Cl. G06F 3/041; H05K 5/00

(52) U.S. Cl. CPC G06F 3/0412; H05K 5/0017
USPC 345/173; 361/679.01

(57) ABSTRACT

A display device includes a display panel that displays an image thereon, a window on the display panel, and an adhesive member between the display panel and the window. The adhesive member is made of an elastic body.

### CROSS REFERENCE TO RELATED APPLICATION

This application claims priority under 35 U.S.C. § 119 to Korean Patent Application No. 10-2012-0122878, filed on Nov. 1, 2012, in the Korean Intellectual Property Office, the entire content of which is incorporated herein by reference.

### BACKGROUND

In recent years, there has been developed a technique using a flexible substrate made of, e.g., at least one of glass, plastic, metal, etc. Since the flexible substrate is light, strong against impact and bendable, the flexible substrate is suitable for a display device of a portable personal terminal or a large-sized display device.

Touch screen panels may be applied to display devices. The touch screen panel is a device that allows a user's command to be input by contacting an object such as a user's hand or pen on the touch screen panel. The touch screen panel outputs an electrical signal by sensing a position at which an object is in contact with the touch screen panel.

### SUMMARY

Embodiments may be realized by providing a display device that includes a display panel displaying an image thereon, a window disposed on the display panel, and an adhesive member interposed between the display panel and the window. The adhesive member is made of an elastic body.

Embodiments may also be realized by providing a display device that includes a display panel displaying an image thereon, a touch screen panel disposed on the display panel, a window disposed on the touch screen panel, a first adhesive member interposed between the display panel and the touch screen panel, and a second adhesive member interposed between the touch screen panel and the window. At least one of the first and second adhesive members is made of an elastic body.

The elastic body may be formed in any one shape of a plurality of balls, a chain and a spring. The elastic body may be made of one selected from the group of an acryl-based material, a silicon-based material, and a polyurethane-based material.

The height of the elastic body may be decreased according to the degree of bending of the display device. The contact area of the elastic body may be increased according to the degree of bending of the display device.

### BRIEF DESCRIPTION OF THE DRAWINGS

The accompanying drawings, together with the specification, illustrate exemplary embodiments, and, together with the description, serve to explain the principles of the embodiments.

FIG. 1 is a sectional view illustrating a display device according to an exemplary embodiment.

FIG. 2 is a sectional view illustrating a display device according to an exemplary embodiment.

FIGS. 3, 4, and 5 are sectional views illustrating adhesive members according to exemplary embodiments.

FIGS. 6, 7, 8, 9A, and 9B are sectional views illustrating various states in which the display device shown in FIG. 1 is bent or folded.

### DETAILED DESCRIPTION

Korean Patent Application No. 10-2012-0122878, filed on Nov. 1, 2012, in the Korean Intellectual Property Office, and entitled: “Display Device” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

The drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements.

FIG. 1 is a sectional view illustrating a display device according to an embodiment of the present invention.

Referring to FIG. 1, the display device according to an exemplary embodiment includes a display panel 10 that is capable of displaying an image thereon, a window 50 disposed on the display panel 10, and an adhesive member 20 interposed between the display panel 10 and the window 50.

The display panel 10 includes two substrates disposed to face each other, and a pixel array disposed between the two substrates. The pixel array is sealed by a sealing member interposed between the two substrates. The sealing member may be separate from the adhesive member 20.

The pixel array has a plurality of pixels connected, for example, in a matrix form between a plurality of scan lines and a plurality of data lines. Each pixel may include, e.g., a liquid crystal or organic light emitting diode. Each pixel may further include a thin film transistor for operating the pixel and a capacitor.

Each of the substrates may have a thin film shape made of a transparent material such as glass or plastic, or made of an opaque material such as metal. The substrates may be configured as flexible substrates that may be bent or folded.

The window 50 may be used to protect a surface of the display panel 10, on which an image is displayed, from an external impact or contact. In a case where the display panel 10 has flexibility, the window 50 may be made of a transparent material that may be bent or folded.

The adhesive member 20 may be used to allow the window 50 to be attached on the display panel 10. The adhesive member 20 may be made of a transparent elastic body having adhesion. For example, the adhesive member 20 may include at least one selected from the group of an acryl-based material, a silicon-based material, and a polyurethane-based material

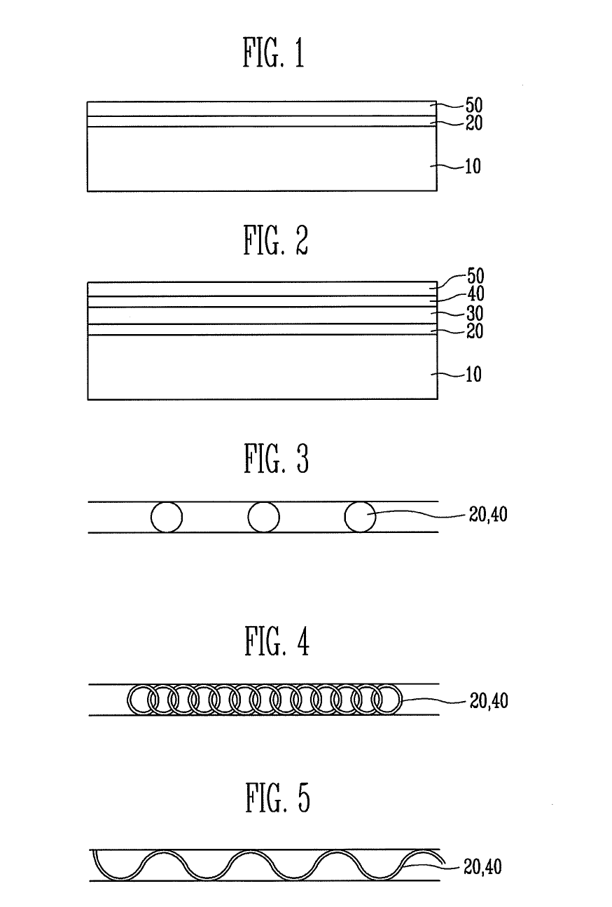

FIG. 2 is a sectional view illustrating a display device according to an exemplary embodiment.

Referring to FIG. 2, the display device according to an exemplary embodiment includes a display panel 10 displaying an image thereon, a touch screen panel 30 disposed on the display panel 10, a window 50 disposed on the touch screen panel 30, a first adhesive member 20 interposed between the display panel 10 and the touch screen panel 30, and a second adhesive member 40 interposed between the touch screen panel 30 and the window 50.

The embodiment of FIG. 2 has a structure in which the touch screen panel 30 is further interposed between the display panel 10 and the window 50. The window 50 may be attached to the touch screen panel 30 by the second adhesive member 40. Primarily the touch screen panel 30 and the second adhesive member 40, which are not described with respect to FIG. 1, will be described.

The touch screen panel 30 may include two transparent substrates or insulation layers disposed to face each other. Two transparent electrodes disposed to face each other may be arranged between the two substrates or insulation layers. A transparent insulation layer may be interposed as a dielectric between the two electrodes.

If a user inputs a command by contacting the window 50 with a user's hand or pen, the touch screen panel 30 recognizes a contact position by sensing a change in capacitance or voltage between the two electrodes. The touch screen panel 30 may be operated in connection with the display panel 10 according to a user's command based on the contact position.

The second adhesive member 40 may be used to allow the window 50 to be attached on the touch screen panel 30. The second adhesive member 40 may be made of a transparent elastic body having adhesion. The second adhesive member 40 may be the same as and/or substantially similar to the first adhesive member 20. For example, the first and second adhesive members 20, 40 may include at least one selected from the group of an acryl-based material, a silicon-based material, and a polyurethane-based material. For example, the first and second adhesive members 20 and 40 may be made of a same material that includes a transparent elastic bodying having adhesion.

FIGS. 3 to 5 are a sectional view illustrating embodiments of the adhesive members 20 and 40.

Referring to FIG. 3, the adhesive member 20 and/or 40 may be configured with a plurality of ball-shaped elastic bodies. The ball-shaped elastic bodies may be regularly or irregularly arranged in a spaced apart pattern, e.g., each of the ball-shaped elastic bodies may be spaced apart from each other. For example, the ball-shaped elastic bodies may have a substantially equal size (height) so that the areas of the elastic bodies contacting the display panel 10 and the touch screen panel 30, and/or the touch screen panel 30 and the window 50, which are respectively disposed beneath and above the elastic bodies, are equal to one another. Each of the ball-shaped elastic bodies may have a spherical shape, e.g., a densely packed with elastic material spherical shape. Further, the ball-shaped elastic bodies may be spaced apart from each other so as to define voids, i.e., regions where the elastic material is excluded, between adjacent ball-shaped elastic bodies.

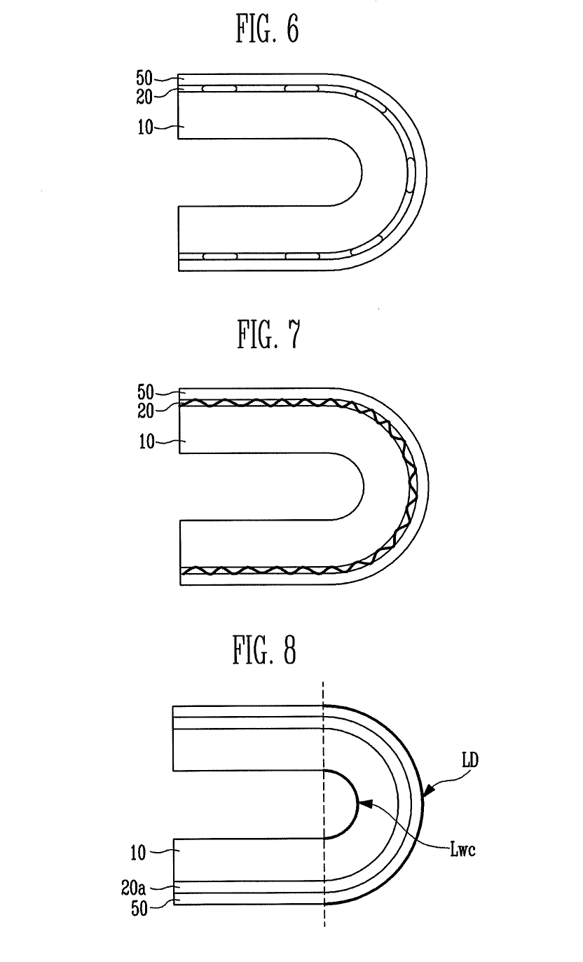

Referring to FIG. 4, the adhesive member 20 and/or 40 may be configured with a chain-shaped elastic body. The chain-shaped elastic body has, e.g., a structure in which a plurality of circular or polygonal rings are interconnected with one another. For example, the plurality of circular or polygonal rings may be arranged in an interlinked pattern so that adjacent ones of the plurality of circular or polygonal rings are directly linked with each other. The plurality of circular or polygonal rings may each surround voids, i.e., regions where elastic material of the elastic bodies of the adhesive members 20 and 40 are excluded. The plurality of rings may have an equal size (height) so that the areas of the elastic bodies contacting the display panel 10 and the touch screen panel 30, and/or the touch screen panel 30 and the window 50, which are respectively disposed beneath and above the plurality of rings, are equal to one another.

Referring to FIG. 5, the adhesive member 20 and/or 40 may be configured with a spring-shaped elastic body. The spring-shaped elastic body has a structure in which circular or semispherical shapes are continuously repeated, e.g., in a waveform shape. The strings-shaped elastic body may be surrounded by voids, i.e., regions where elastic material of the elastic bodies of the adhesive members 20 and 40 are excluded. The circular or semispherical shapes may have an equal size (height as measured with respect to peaks of the spring-shaped elastic body) so that the areas of the elastic bodies contacting the display panel 10 and the touch screen panel 30, and/or the touch screen panel 30 and the window 50, which are respectively disposed beneath and above the circular or semispherical shapes, are equal to one another.

Although it has been described in these embodiments in that both the adhesive members 20 and 40 are made of a transparent elastic body, one of the adhesive members 20 and 40 may be made of a transparent elastic body. For example, the adhesive member 20 may be made of a transparent elastic body, and the adhesive member 40 may be made of an adhesive such as an optical clear adhesive (OCA).

FIGS. 6 to 9 are sectional views illustrating states in which the display device shown in FIG. 1 is bent or folded.

FIG. 6 illustrates a structure in which the adhesive member 20 of FIG. 3 is applied to the display device of FIG. 1. FIG. 7 illustrates a structure in which the adhesive member 20 of FIG. 5 is applied to the display device of FIG. 1. The structure of the adhesive member 20 in FIG. 4 may also be applied to the display device of FIG. 1. Similarly, the structure of the adhesive member 20, 40 in FIGS. 3-5 may be applied to the display device of FIG. 2.

Referring to FIGS. 6 and 7, if the display panel 10 and the window 50 are bent or folded, the height of the adhesive member 20 is decreased by pressure. In this case, the adhesive member 20 maintaining the contact with the display panel 10 and the window 50 by means of elasticity is deformed from a circular shape to an elliptical shape so as to come in surface contact with the display panel 10 and the window 50, e.g., as illustrated in FIG. 6. According to another exemplary embodiment, the amplitude of the spring-shaped elastic body shape may be decreased, e.g., as illustrated in FIG. 7. Accordingly, when the display panel 10 and the window 50 are bent, the contact area of the adhesive member 20 with the display panel 10 and the window 50 is increased.

For example, in a case where an adhesive member 20a is formed to have a certain thickness without having elasticity, e.g., as shown in FIG. 8, the inner circumference Lwc of the display device has a smaller value than the outer circumference LD of the display device, based on a point (line A) at which the bending of the display device occurs. The difference between the outer circumference LD and the inner circumference Lwc acts as a cause of stress, and therefore, deformation or delamination of the display device may be caused.

The stress caused by the difference between the outer circumference LD and the inner circumference Lwc may be decreased to reduce the possibility of and/or prevent the deformation or delamination of the display device. The difference between the outer circumference LD and the inner circumference Lwc may also be decreased to reduce the stress.

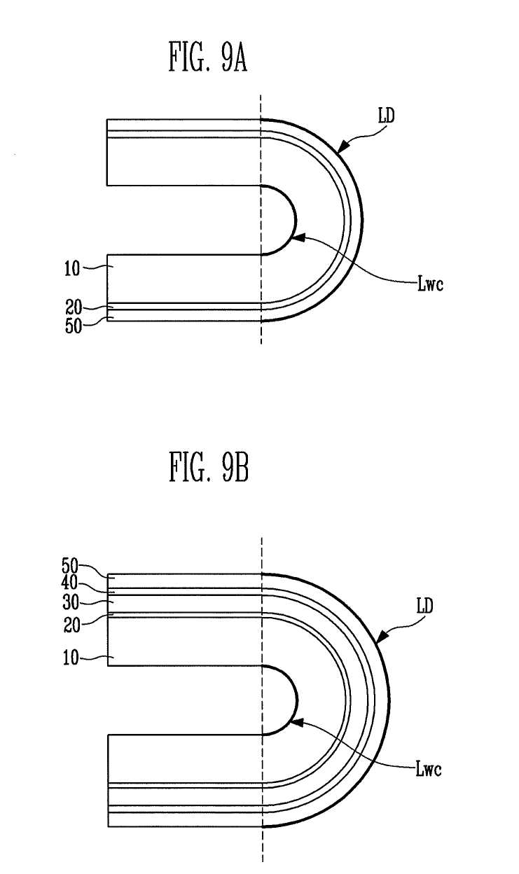

According to an exemplary embodiment, in a case where the display panel 10 and the window 50 are bent or folded, the pressure is applied to the adhesive member 20 made of an elastic body, and thus the thickness (height) of the adhesive member 20 is decreased as shown in FIG. 9A. For example, the stress caused by the difference between the outer circumference LD and the inner circumference Lwc may be applied to the adhesive member 20. The difference between the outer circumference LD and the inner circumference Lwc may be decreased, and hence the stress may be minimized.

FIG. 9A illustrated an exemplary embodiment in which the adhesive layer 20 is between the display panel 10 and the window 50. However, one of ordinary skill art would recognize the adhesive member 40 may be similarly arranged between the touch screen panel 30 and the window 50 as shown in FIG. 9B. If the display device becomes flat, the adhesive members 20 and 40 are recovered by the elasticity so that the original shapes of the adhesive members 20 and 40 are maintained.

By way of summation and review, a touch screen panel combined with a flexible substrate is being developed. The touch screen panel may be attached to a display panel by an adhesive such as an optical clear adhesive (OCA). However, the adhesive is formed to have a certain thickness, and both surfaces of the adhesive form adhesive surfaces. Therefore, in a case where a flexible display device is bent or folded due to a wide adhesive area thereof, stress or deformation may be caused. The stress or deformation increases as the thickness or adhesive area of the adhesive increases. In a serious case, delamination may occur in the display panel or the touch screen panel.

In contrast, embodiments relate to a display device capable of minimizing stress or delamination due to bending thereof. Embodiments also relate to a display device capable of minimizing stress when being bent or folded. Embodiments further relate to a display device capable of reducing the possibility of and/or preventing delamination of a display panel, a touch screen panel, and a window. Embodiments also relate to a display device that when it is in a bent or folded state, a thickness (height) of an adhesive member is decreased so that stress or deformation of the display device may be minimized.

In the display device according to an exemplary embodiment, a display panel, a touch screen panel, and a window are adhered to one another by an adhesive member made of an elastic body. In a case where the display device is bent or folded, the thickness of the adhesive member is decreased by pressure, so that stress or deformation of the display device may be minimized, thereby reducing the possibility of and/or preventing delamination of the display device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display device, comprising:
a display panel that displays an image thereon;
a window on the display panel; and
an adhesive member between the display panel and the window, the adhesive member being made of an elastic body.

2. The display device of claim 1, wherein the elastic body has a shape of a plurality of balls, a chain, or a spring.

3. The display device of claim 1, wherein the elastic body is made of one selected from the group of an acryl-based material, a silicon-based material, and a polyurethane-based material.

4. The display device of claim 1, wherein a height of the elastic body decreases according to a degree of bending of the display device.

5. The display device of claim 1, wherein a contact area of the elastic body with the display panel increases according to a degree of bending of the display device.

6. A display device, comprising:
a display panel that displays an image thereon;
a touch screen panel on the display panel;
a window on the touch screen panel;
a first adhesive member between the display panel and the touch screen panel; and
a second adhesive member between the touch screen panel and the window, at least one of the first and second adhesive members being made of an elastic body.

7. The display device of claim 6, wherein the elastic body has a shape of a plurality of balls, a chain, or a spring.

8. The display device of claim 6, wherein the elastic body is made of one selected from the group of an acryl-based material, a silicon-based material, and a polyurethane-based material.

9. The display device of claim 6, wherein a height of the elastic body decreases according to a degree of bending of the display device.

10. The display device of claim 6, wherein a contact area of the elastic body with the display panel increases according to a degree of bending of the display device.
